(19) United States
(12) Patent Application Publication
(10) Pub. No.: US 2026/0333742 A1
(43) Pub. Date: Oct. 22, 2026

(54) DUAL GATE LDMOS DRIVERS

(71) Applicant: Renesas Electronics America Inc., Milpitas, CA (US)

(72) Inventors: Anurag KAPLISH, Milpitas, CA (US); Meng Chia LEE, Milpitas, CA (US); Kijeong HAN, Milpitas, CA (US); Gourab SABUI, Milpitas, CA (US); Marco ZUNIGA, Milpitas, CA (US)

(73) Assignee: Renesas Electronics America Inc., Milpitas, CA (US)

(21) Appl. No.: 19/423,330

(22) Filed: Dec. 17, 2025

Related U.S. Application Data
(60) Provisional application No. 63/790,930, filed on Apr. 18, 2025.

(51) Int. Cl. H10D 30/60; H02M 3/158; H10D 30/65; H10D 62/13; H10D 84/80; H10D 64/00

(52) U.S. Cl. CPC H10D 30/611; H02M 3/158; H10D 30/65; H10D 62/154; H10D 84/811; H10D 64/111

(57) ABSTRACT

A switching regulator includes a high-side switch and a low-side switch coupled in series between an input voltage and a ground potential via a common terminal. An inductor is coupled to the common terminal, and an output capacitor is configured to generate an output voltage based on a current flowing through the inductor. The high-side switch is a first dual-gate MISFET including a first gate, a second gate, a first source and a first drain. The first dual-gate MISFET has a first current path and a second current path, which are paths of a current flow from the first source to the first drain within the first dual-gate MISFET. The first gate controls current flow through the first current path, and the second gate controls current flow through the second current path. A length of the second current path is longer than a length of the first current path.

This application claims the benefit under 35 U.S.C. §119(e) of U.S. Provisional Application No. 63/790,930, filed on Apr. 18, 2025, titled “RESURF AND MULTI-GATE TECHNIQUES FOR LDMOS DEVICES,” the entire disclosure of which is incorporated by reference herein.

### BACKGROUND

The present disclosure generally relates to the field of semiconductor device fabrication, and more particularly to lateral drain-extended metal-oxide-semiconductor (LDMOS) transistors and associated dual-gate driver architectures.

Drain-extended metal-oxide-semiconductor (DMOS) transistors combine high voltage tolerance, high current capability, fast switching characteristics, and robust performance, making them a superior choice for many power electronics applications. Bipolar-CMOS-DMOS (BCD) technology has become the mainstream process for power management integrated circuits (PMICs), with the DMOS transistor serving as the primary power processing device. Among various DMOS structures, lateral DMOS (LDMOS) transistors have gained wide adoption in PMICs and radio frequency (RF) power applications due to their compact layout and ease of integration with CMOS and bipolar circuitry.

Power devices represent some of the largest contributors to die size and overall cost in PMICs. The specific on-resistance, Rsp (typically expressed in units of mΩ·mm²), is one of the principal figures of merit for DMOS power devices utilized in the linear region of operation. Rsp reflects the die-area utilization efficiency of the device for a given on-state resistance RDSON.

Compact power devices with low Rsp are highly desirable, and LDMOS transistors can be engineered to minimize this parameter. However, reducing Rsp in lateral structures often introduces competing trade-offs. For instance, lowering the on-resistance typically requires increasing the channel width or reducing the drift-region resistance, both of which can undesirably increase parasitic capacitance, degrade breakdown voltage, or complicate gate and field-plate design. Similarly, aggressive scaling of lateral device dimensions or field-oxide thickness to reduce resistance can lead to electric-field crowding and hot-carrier degradation, adversely affecting device reliability and long-term performance.

### SUMMARY

According to an embodiment of the present disclosure, a switching regulator includes a high-side switch and a low-side switch coupled in series between an input voltage and a ground potential via a common terminal, an inductor coupled to the common terminal, and an output capacitor configured to generate an output voltage based on a current flowing through the inductor. The high-side switch is a first dual-gate MISFET including a first gate, a second gate, a first source and a first drain, the first dual-gate MISFET has a first current path and a second current path, which are paths of a current flow from the first source to the first drain within the first dual-gate MISFET, the first gate controls a current flow through the first current path, the second gate controls a current flow through the second current path, and a length of the second current path is longer than a length of the first current path.

According to another embodiment of the present disclosure, a switching regulator includes a high-side switch and a low-side switch coupled in series between an input voltage and a ground potential via a common terminal, an inductor coupled to the common terminal, and an output capacitor configured to generate an output voltage based on a current flowing through the inductor. The high-side switch is a first dual-gate MISFET including a first gate, a second gate, a first source and a first drain, the first dual-gate MISFET has a first current path and a second current path, which are paths of a current flow from the first source to the first drain within the first dual gate MISFET, the first gate controls a current flow through the first current path, and the second gate controls a current flow through the second current path. The low-side switch is a second dual gate MISFET including a third gate, a fourth gate, a second source and a second drain, the second dual gate MISFET has a third current path and a fourth current path, which are paths of a current flow from the second source to the second drain within the second dual gate MISFET, the third gate controls a current flow through the third current path, the fourth gate controls a current flow through the fourth current path, a length of the second current path is longer than a length of the first current path, and a length of the fourth current path is longer than a length of the third current path.

According to yet another embodiment of the present disclosure, a switching regulator includes an inductor and a high-side switch coupled in series between an input voltage and an output voltage via a common terminal, a low-side switch coupled between the common terminal and a ground potential, and an output capacitor configured to generate the output voltage based on a current flowing through the inductor. The high-side switch is a first dual-gate MISFET including a first gate, a second gate, a first source and a first drain, the first dual-gate MISFET has a first current path and a second current path, which are paths of a current flow from the first source to the first drain within the first dual gate MISFET, the first gate controls a current flow through the first current path, the second gate controls a current flow through the second current path, and a length of the second current path is longer than a length of the first current path.

According to yet another embodiment of the present disclosure, a switching regulator includes an inductor and a high-side switch coupled in series between an input voltage and an output voltage via a common terminal, a low-side switch coupled between the common terminal and a ground potential, and an output capacitor configured to generate the output voltage based on a current flowing through the inductor. The high-side switch is a first dual-gate MISFET including a first gate, a second gate, a first source and a first drain, the first dual-gate MISFET has a first current path and a second current path, which are paths of a current flow from the first source to the first drain within the first dual-gate MISFET, the first gate controls a current flow through the first current path, and the second gate controls a current flow through the second current path. The low-side switch is a second dual-gate MISFET including a third gate, a fourth gate, a second source and a second drain, the second dual-gate MISFET has a third current path and a fourth current path, which are paths of a current flow from the second source to the second drain within the second dual-gate MISFET, the third gate controls a current flow through the third current path, the fourth gate controls a current flow through the fourth current path, a length of the second current path is longer than a length of the first current path, and a length of the fourth current path is longer than a length of the third current path.

### BRIEF DESCRIPTION OF THE DRAWINGS

The following detailed description, given by way of example and not intended to limit the embodiments described herein, will best be appreciated in conjunction with the accompanying drawings, in which:

FIG. 1A illustrates a switching regulator configured as a buck converter, according to an embodiment of the present disclosure;

FIG. 1B illustrates a symbol representation of a dual-gate MISFET, according to an embodiment of the present disclosure;

FIG. 1C illustrates a cross-sectional view of a semiconductor device including a dual-gate configuration that may be used as either high-side or low-side switch in FIG. 1A, according to embodiments of the present disclosure;

FIG. 1D illustrates a symbol representation of a dual-gate MISFET including a field-plate electrode, according to an embodiment of the present disclosure;

FIG. 1E illustrates a cross-sectional view of a semiconductor device including the dual-gate configuration and a field plate disposed over a drift layer, according to embodiments of the present disclosure;

FIG. 1F illustrates a switching regulator configured as a buck converter in which both high-side switch and low-side switch are dual-gate MISFETs, according to an embodiment of the present disclosure;

FIG. 1G illustrates a block diagram of a switching regulator including a controller, high-side gate drivers, low-side gate drivers, and a bootstrap circuit, according to an embodiment of the present disclosure;

FIG. 2A illustrates a switching regulator configured as a boost converter, according to an embodiment of the present disclosure;

FIG. 2B illustrates a switching regulator 200A configured as a boost converter in which both high-side switch and low-side switch are dual-gate MISFETs, according to an embodiment of the present disclosure;

FIG. 2C illustrates a block diagram of a switching regulator configured as a boost converter, according to an embodiment of the present disclosure;

FIG. 3 illustrates representative dual-gate driver examples together with a corresponding timing diagram, according to an embodiment of the present disclosure;

FIG. 4 illustrates logic-controlled driver configurations using logic gates and optional delay elements to generate gate-drive signals, according to an embodiment of the present disclosure;

FIG. 5 illustrates alternative driver configurations including optional delay elements and threshold-comparison stages, according to an embodiment of the present disclosure;

FIG. 6 illustrates dual-gate driver examples including logic architectures, according to an embodiment of the present disclosure; and

FIG. 7 illustrates additional driver configurations that integrate comparator-based threshold detection with logic delay circuitry, according to an embodiment of the present disclosure.

The drawings are not necessarily to scale. The drawings are merely schematic representations, not intended to portray specific parameters of the embodiments in the present disclosure. The drawings are intended to depict typical embodiments of the present disclosure. In the drawings, like numbering represents like elements.

### DETAILED DESCRIPTION

Detailed embodiments of the claimed structures and methods are disclosed herein; however, it can be understood that the disclosed embodiments are merely illustrative of the claimed structures and methods that may be embodied in various forms. The claimed structures and methods may, however, be embodied in many different forms and should not be construed as limited to the exemplary embodiments set forth herein. In the description, details of various conventional features and techniques may be omitted to avoid unnecessarily obscuring the presented embodiments.

For purposes of the description hereinafter, terms such as “upper”, “lower”, “right”, “left”, “vertical”, “horizontal”, “top”, “bottom”, and derivatives thereof shall relate to the disclosed structures and methods, as oriented in the drawing figures. Terms such as “above”, “overlying”, “atop”, “on top”, “positioned on” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating or semiconductor layers at the interface of the two elements.

In the interest of not obscuring the presentation of embodiments of the present disclosure, in the following detailed description, some processing steps or operations that may be ordinary in the art may have been combined together for presentation and for illustration purposes and in some instances may have not been described in detail. In other instances, some processing steps or operations that may be ordinary in the art may not be described at all. It should be understood that the following description is rather focused on the distinctive features or elements of various embodiments of the present disclosure.

Compact LDMOS power devices are designed to minimize the specific on-resistance Rsp to achieve high current capability and efficient die utilization. In a standard LDMOS device, the half-pitch, defined as the distance between the middle of the body region and the middle of the drain region, plays a critical role in determining Rsp. A smaller pitch generally results in lower Rsp. However, aggressive pitch scaling adversely impacts the breakdown voltage (BVDSS) and hot-carrier injection (HCI) performance due to increased electric-field crowding and non-uniform potential distribution in the drift region. Thus, a fundamental trade-off exists between minimizing Rsp and BVDSS/HCI performance.

To address this trade-off, embodiments of the present disclosure provide LDMOS structures incorporating a second gate electrode in addition to the primary gate. The second gate provides an additional current control path (Path 2) extending from the drain to the source. This dual-gate configuration improves device control and field distribution within the drift region. The proposed embodiments may enhance BVDSS and RDSON figure of merit, lower Miller coupling, and improve HCI lifetime compared to traditional single-gate LDMOS devices which makes the dual-gate structure particularly suitable for integration in advanced BCD and power management processes.

Embodiments of the present disclosure further provide methods and driver circuit configurations for driving and biasing the first and second gates of the dual-gate LDMOS device, including static and dynamic driving schemes capable of independently or simultaneously controlling the gate potentials to maintain optimal electric-field distribution and switching characteristics under various operating conditions.

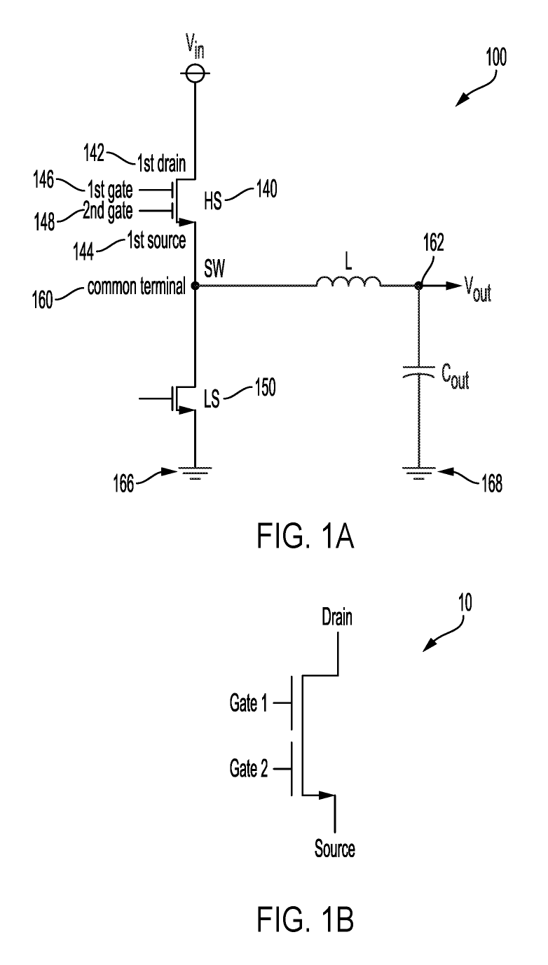

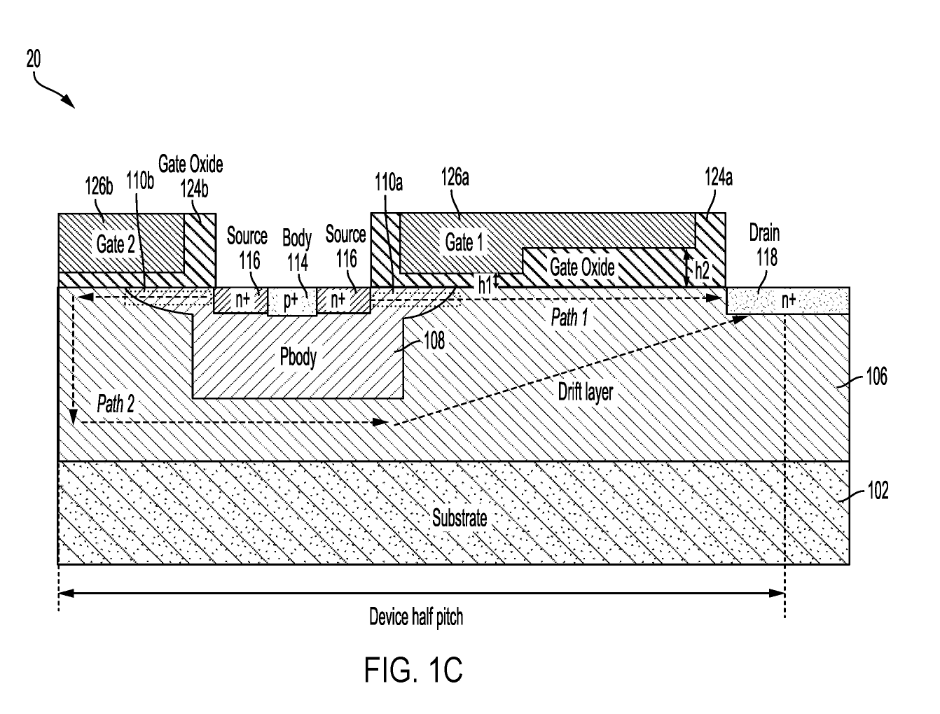

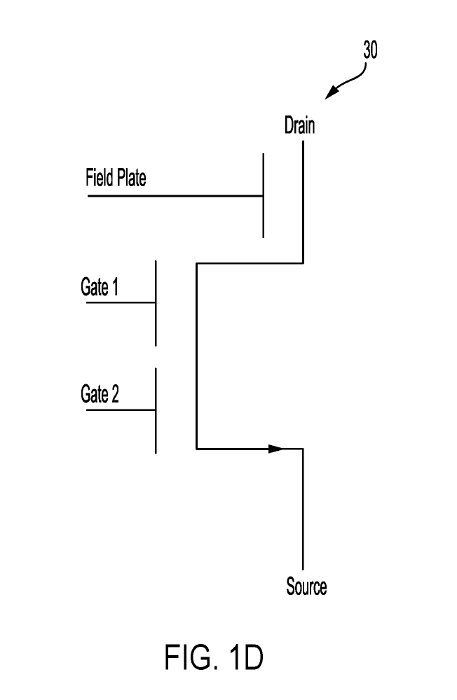

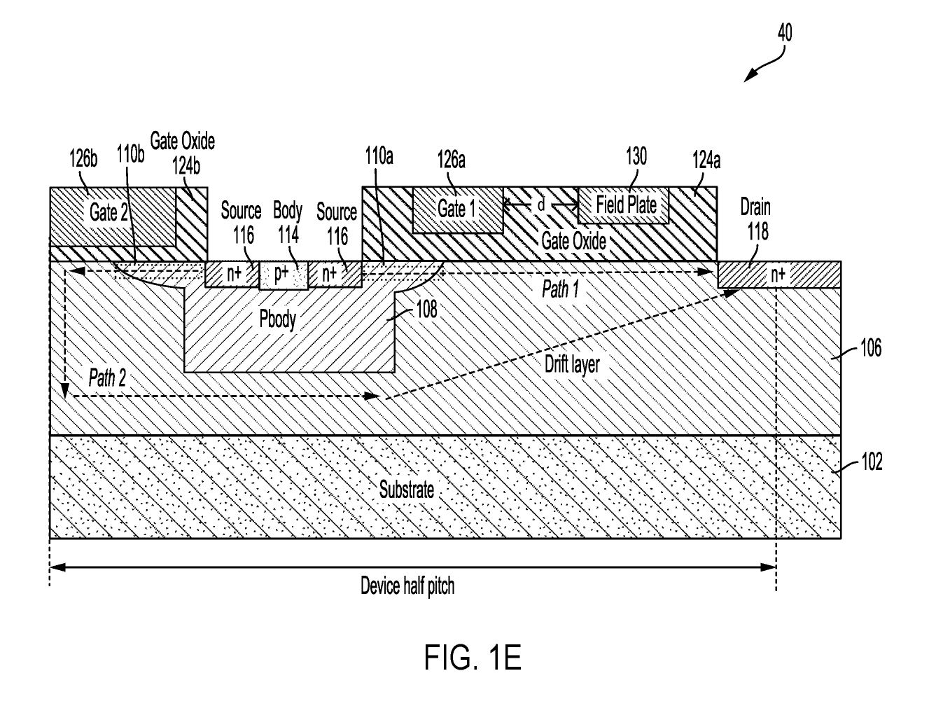

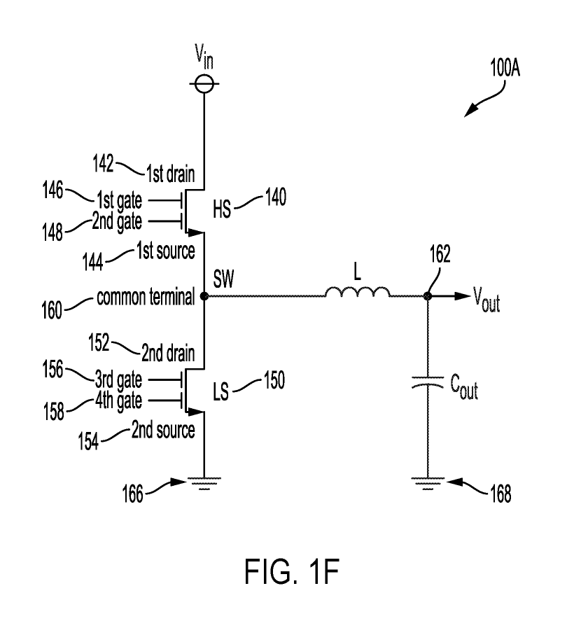

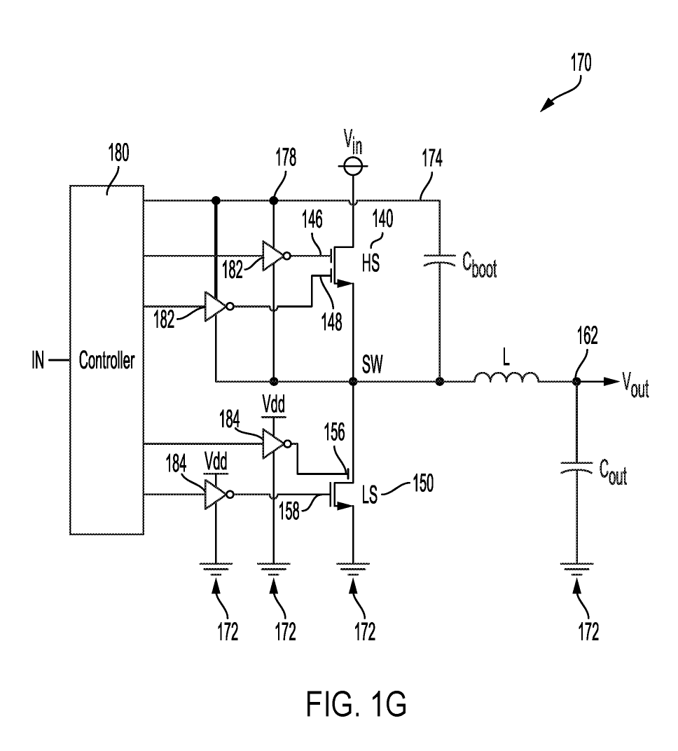

Embodiments by which the dual-gate LDMOS devices and associated driver circuits can be implemented are described in detail below with reference to the accompanying drawings in FIGS. 1A-7.

FIG. 1A illustrates a switching regulator 100 configured as a buck converter, according to an embodiment of the present disclosure.

The switching regulator 100 (buck converter) is configured to step down an input voltage (Vin) to generate an output voltage (Vout). The switching regulator 100 includes a high-side (HS) switch 140 and a low-side (LS) switch 150 coupled in series between the input voltage Vin and a ground potential 166 through a common terminal 160 (switching node SW). In the context of the present disclosure, the common terminal 160 corresponds to the switching node SW, at which the high-side switch 140 and the low-side switch 150 are coupled in series. An inductor L is coupled to the common terminal 160, and an output capacitor Cout is connected between an output node 162 and a ground potential 168 to smooth the output voltage Vout derived from a current flowing through the inductor L.

In this embodiment, the high-side switch 140 is implemented as a first dual-gate metal-insulator-semiconductor field-effect transistor (MISFET) such as a laterally diffused MOSFET (LDMOSFET), while the low-side switch 150 is implemented as a standard single-gate MOSFET. The high-side switch 140 (i.e., the high-side dual-gate MISFET) includes a first gate electrode 146, a second gate electrode 148, a first source 144, and a first drain 142.

The first and second gates 146 and 148 are independently controlled by separate gate drivers, enabling selective or sequential activation to tailor the device’s switching behavior. For instance, the second gate 148 may be activated slightly before or after the first gate 146 to shape the transient current distribution within the LDMOS channel, thereby optimizing the trade-off between conduction loss and switching speed. In various embodiments, either the first gate or the second gate may be activated before the other gate during a switching transition, depending on the driver configuration. Any of the activation sequences described herein may be used to control current distribution in the described embodiments.

FIG. 1B schematically represents a symbol representation 10 of a dual-gate MISFET, while FIG. 1C illustrates a cross-sectional view of a corresponding semiconductor device 20 incorporating the dual-gate configuration that may be used as either the high-side or low-side switch in FIG. 1A, according to embodiments of the present disclosure.

The semiconductor device 20 may be formed on a semiconductor substrate (hereinafter “substrate”) 102, which may be a silicon or SOI substrate. The substrate 102 may have a thickness suitable for mechanical support and for isolating high-voltage regions from the bulk.

A drift layer 106 of a first conductivity type is disposed over the substrate 102. For example, when the semiconductor device 20 is an n-channel DMOS transistor, the first conductivity type of the drift layer 106 is n-type. The drift layer 106 may be epitaxially grown to a desired thickness and doping concentration that establishes a predetermined breakdown voltage (BVDSS). In some embodiments, the drift layer 106 may be a laminate structure including a first drift layer and a second drift layer (not shown) laminated in that order from the substrate 102 upward. The drift layer 106 laterally extends between a body region (or body) 114 on one side and a drain region (or drain) 118 on the opposite side, defining a device half-pitch as shown in FIG. 1C.

A p-body region (also referred to as p-body) 108 of a second conductivity type (e.g., p-type) opposite to that of the drift layer 106 is formed in an upper portion of the drift layer 106, typically by ion implantation followed by thermal activation. The p-body region 108 serves to form a p-n junction with the drift layer 106 to support high-voltage operation. Within the p-body region 108, a source region (or source) 116 of the first conductivity type is formed, for example by shallow implantation and annealing. The source region 116 provides a low-resistance contact for carrier injection during device conduction. A heavily doped p+ contact region may optionally be provided within the body region 114 to ensure reliable body contact and to suppress parasitic bipolar effects.

A first gate electrode 126a (Gate 1) and a second gate electrode 126b (Gate 2) are formed over the body region 108 and the drift layer 106. The p-body region 108 is located between the first gate electrode 126a and the second gate electrode 126b. A first gate oxide 124a is disposed below the first gate electrode 126a and defines a first channel region 110a. A second gate oxide 124b is disposed below the second gate electrode 126b and defines a second channel region 110b. A first current path (also referred to as Path 1) is a path of current flow from the source region 116 to the drain region 118 through the drift layer 106 directly across the body region 108, without detouring around the body region 108. More particularly, the first current path (Path 1) extends from the source region 116 through the first channel region 110a and into the drift layer 106 toward the drain region 118. A second current path (also referred to as Path 2) is a path of current flow from the source region 116 to the drain region 118 that detours around the body region 108. More particularly, the second current path (Path 2) extends from the source region 116 through the second channel region 110b and laterally across a longer portion of the drift layer 106 before reaching the drain region 118. Accordingly, a length of Path 2 is greater than a length of Path 1, which may enable controlled current sharing between short and long lateral paths. The first and second gate electrodes 126a and 126b may be composed of polysilicon, metal gate material (such as TiN, W, or Al), or a combination thereof, and may be patterned using conventional lithography and etching techniques.

The first gate oxide 124a includes a thin gate-oxide portion of first thickness h₁ and a thicker oxide portion of second thickness h₂ that laterally extends toward the drift layer 106. The thin portion (h₁) provides efficient gate control, while the thicker portion (h₂) moderates the electric field near the drain side of the first gate electrode 126a. The first thickness h₁ may range from approximately 1 nm to 100 nm, and the second thickness h₂ may range from approximately 1 nm to 5 µm or less, depending on the device voltage rating. The first gate oxide 124a may be a thermally grown silicon dioxide (SiO₂) or a stacked oxide/nitride/oxide (ONO). The second gate oxide 124b may be formed of the same or a different material as the first gate oxide 124a and may be fabricated simultaneously with or separately from the first gate oxide 124a. In some embodiments, the second gate oxide 124b may have the same thickness (h₁) as the thin gate-oxide portion of the first gate oxide 124a. In other embodiments, the second gate oxide 124b may be locally thicker to reduce gate-to-drain coupling for the longer Path 2. When the drift layer 106 is implemented as a laminated structure, the first current path (Path 1) may extend predominantly through the second drift layer (top layer) without detouring around the body region 108, whereas the second current path (Path 2) may extend through both the first and second drift layers (top and bottom layers) while bypassing (i.e., going around) the body region 108.

The first and second gate electrodes 126a and 126b may be formed of polysilicon, metal, or a metal-nitride stack, and are patterned using conventional lithography and etching techniques. Independent biasing of the first and second gate electrodes 126a and 126b allows simultaneous or staggered activation, providing flexible control over the current distribution in Path 1 and Path 2. This dual-gate architecture may enable staged conduction and adjustable delay operation to improve switching efficiency, reduce transient current spikes, and enhance breakdown-voltage robustness in the drift layer 106. Accordingly, the dual-gate MISFET of FIG. 1C provides a first current path and a second current path within the same device, with the first gate electrode 126a controlling the current flow through the first current path (Path 1) and the second gate electrode 126b controlling the current flow through the second current path (Path 2), and with the second current path being longer than the first current path.

When implemented in the switching regulator 100 of FIG. 1A, the dual-gate MISFET of FIG. 1C functions as the high-side switch 140 (or alternatively as the low-side switch 150) and can be driven by separate gate-driver circuits to control each gate independently. The independent control of the first and second gate electrodes 126a and 126b enables dynamic modulation of the current flow through the short and long conduction paths, allowing the regulator to achieve lower switching loss during transient transitions and higher conduction efficiency under steady-state operation. This structure may provide improved switching performance and reliability across a wide range of operating voltages and load conditions.

FIG. 1D schematically shows a symbol representation 30 of a dual-gate MISFET including a field-plate electrode, while FIG. 1E illustrates a cross-sectional view of a corresponding semiconductor device 40 incorporating the dual-gate configuration and a field plate 130 disposed over the drift layer 106, according to embodiments of the present disclosure.

In FIG. 1E, the same reference numerals are used to identify components identical or similar to those in FIG. 1C, and detailed descriptions of such components are omitted to avoid unnecessary repetition.

In this embodiment, the first gate electrode 126a (Gate 1) and the second gate electrode 126b (Gate 2) are formed over respective channel regions 110a and 110b, defining the first and second current paths (Path 1 and Path 2) that extend laterally through the drift layer 106. A field plate 130 is positioned above the drift layer 106, between the first gate electrode 126a and the drain region 118. The field plate 130 is electrically isolated from the underlying semiconductor by the first gate oxide 124a, as depicted in FIG. 1E. The first gate electrode 126a, the second gate electrode 126b, and the field plate 130 are physically separate from one another on the device surface and are configured to be controlled independently of each other by respective bias or drive signals.

The field plate 130 is separated from the first gate electrode 126a (Gate 1) by a distance d, defining a lateral spacing that influences the peak electric-field distribution and capacitance coupling between the gate and drift layer 106. The distance d may vary between approximately 1 nm and approximately 10 µm, depending on the voltage class of the device and the desired balance between breakdown voltage and switching speed. The field plate 130 may be biased to a fixed potential (e.g., source, gate, or an intermediate bias voltage) or driven dynamically by a dedicated control circuit to tailor the electric-field profile during operation. The field plate 130 may be formed of the same conductive material as the first and second gate electrodes 126a and 126b and patterned in a separate or simultaneous masking step. In some embodiments, the first gate electrode 126a, the second gate electrode 126b, and the field plate 130 each receive bias from a different node of an external or integrated driver circuit so that their potentials can be adjusted independently during switching transients.

The inclusion of the field plate 130 in combination with the dual-gate structure may provide enhanced control over the lateral electric field and charge distribution within the drift layer 106. Although only a single field plate 130 is illustrated in FIG. 1E, additional field plates may be employed in other embodiments to further shape the electric-field profile, depending on the design requirements and operating voltage of the device.

FIG. 1F illustrates a switching regulator 100A configured as a buck converter in which both the high-side (HS) switch 140 and low-side (LS) switch 150 are dual-gate MISFETs, according to an embodiment of the present disclosure.

In this embodiment, the high-side switch 140 includes the first drain 142, the first source 144, the first gate 146, and the second gate 148. The first and second gates 146 and 148 control conduction along two parallel current paths extending from the first source 144 to the first drain 142 within the high-side device. The low-side switch 150 includes a second drain 152, a second source 154, a third gate 156, and a fourth gate 158, which respectively control conduction through two corresponding current paths within the low-side device. The first source 144 (high-side source) and the second drain 152 (low-side drain) are connected in common at the switching node SW (common terminal 160) to define the midpoint of the half-bridge configuration.

Each of the first, second, third, and fourth gates 146, 148, 156, and 158 is driven independently by a corresponding gate-driver circuit under the control of a controller (not shown in this figure). The controller may operate the high-side and low-side gate groups in a complementary manner, such that when the high-side switch 140 is turned ON, the low-side switch 150 is turned OFF, and vice versa, thereby generating a pulse-width-modulated switching voltage at switching node SW. Within each switching device, the paired gates (e.g., first and second gates 146 and 148 in the high-side switch 140, and third and fourth gates 156 and 158 in the low-side switch 150) may be switched either simultaneously or with a controlled delay. Such timing offsets can shape current distribution between shorter and longer channel paths in the dual-gate LDMOS structures.

The switching regulator 100A therefore represents a fully dual-gate implementation of the converter architecture previously shown in FIG. 1A. While the embodiment of FIG. 1F illustrates both the high-side and low-side switches as dual-gate MISFETs, in other embodiments one of the switches may be implemented as a single-gate transistor while the other is a dual-gate transistor, depending on the desired cost, voltage, and performance requirements. The use of independently controlled gates in both the high-side and low-side devices provides an additional degree of freedom in tuning dead-time, balancing transient currents, and achieving high-efficiency operation across a wide load range.

FIG. 1G illustrates a block diagram of a switching regulator 170 including a controller 180, high-side gate drivers 182, low-side gate drivers 184, and a bootstrap circuit 174, according to an embodiment of the present disclosure.

The controller 180 receives an input control signal (IN) and generates complementary control signals for the high-side switch 140 and the low-side switch 150. The high-side switch 140 includes the first gate 146 and the second gate 148, while the low-side switch 150 includes the third gate 156 and the fourth gate 158. The high-side gate drivers 182 are configured to drive the first and second gates 146, 148 independently, enabling sequential or simultaneous activation of the respective gate electrodes within the dual-gate high-side MISFET. Likewise, the low-side gate drivers 184 independently drive the third and fourth gates 156, 158 of the dual-gate low-side MISFET. Each of the low-side gate drivers 184 is supplied with a driver supply voltage Vdd that provides the required potential to fully enhance the low-side switch 150 during operation. The controller 180 coordinates the high-side and low-side gate drivers 182, 184 such that the corresponding gate pairs gates (e.g., first and second gates 146 and 148 in the high-side switch 140, and third and fourth gates 156 and 158 in the low-side switch 150) are driven in a complementary manner to prevent cross-conduction and to control the switching cycle.

The bootstrap circuit 174 includes a bootstrap capacitor (Cboot) coupled between a supply node 178 of the high-side gate drivers 182 and the switching node SW. During operation, the bootstrap circuit 174 generates a boosted voltage above the switching-node potential, thereby supplying a proper gate-drive voltage for the high-side dual-gate MISFET (i.e., the high-side switch 140). This boosted voltage allows full enhancement of both the first and second gates 146, 148 even as the source potential of the high-side switch 140 rises toward the input voltage Vin, ensuring stable and efficient turn-on behavior.

The controller 180, high-side gate drivers 182, and low-side gate drivers 184 may be implemented as discrete circuits or integrated within the same die or package as the power transistors. The dual-gate drive scheme described herein can also be extended to other converter topologies such as synchronous boost, half-bridge, or multi-level power regulators, providing flexible gate-timing control, reduced switching losses, and improved overall efficiency.

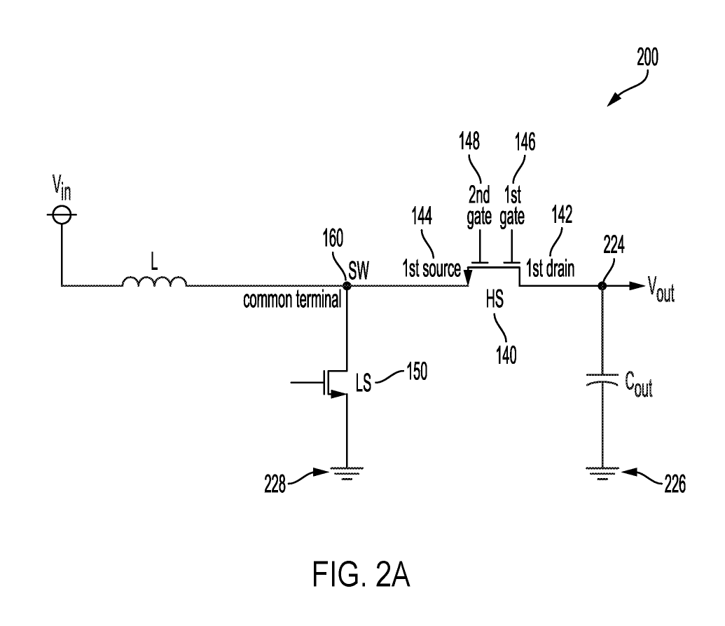

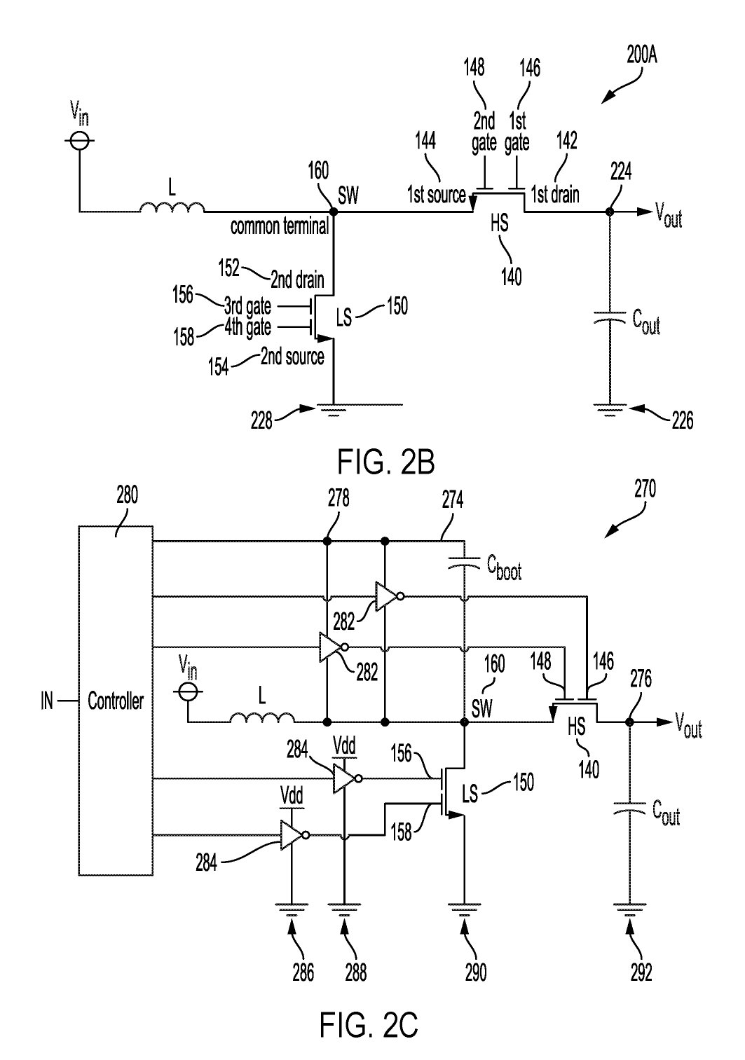

FIG. 2A illustrates a switching regulator 200 configured as a boost converter, according to an embodiment of the present disclosure. To avoid redundancy, components identical or similar to those described with reference to FIGS. 1A-1G are denoted by the same reference numerals and their detailed descriptions are omitted. In the illustrated boost configuration, the inductor L and the high-side switch 140 are coupled in series between the input voltage Vin and an output node 224 via the common terminal 160 (switching node SW), and the low-side switch 150 is coupled between the common terminal 160 and a ground potential 228.

Specifically, in this embodiment, the high-side switch (HS) 140 is implemented as a dual-gate MISFET including the first drain 142, the first source 144, the first gate 146, and the second gate 148. The first source 144 is coupled to the common terminal 160 (switching node SW) that is connected to the inductor L and to the low-side (LS) switch 150. The first drain 142 is connected to an output node 224 to generate the regulated output voltage Vout, while an output capacitor Cout is connected between the output node 224 and a ground potential 226 to smooth the output. The low-side switch 150 is coupled between the common terminal 160 and a ground potential 228 and may be implemented as a single-gate transistor (for example, a standard N-channel MOSFET).

During operation, energy is stored in the inductor L when the low-side switch 150 is turned ON and released to the output node 224 when the high-side switch 140 is turned ON. The high-side switch 140 (i.e., the dual-gate MISFET) is driven by independent control signals applied to the first and second gates 146 and 148 to regulate current conduction from the common terminal 160 toward the output node 224. The first gate 146 may initiate conduction through a shorter channel path to enable fast turn-on and reduced switching loss, whereas the second gate 148 may be activated with a controlled delay to expand the conduction path area and lower on-resistance once the transition stabilizes. The dual-gate operation thus enables improved control over the boost switching transition, mitigating voltage overshoot and enhancing conversion efficiency.

While FIG. 2A illustrates an embodiment in which only the high-side switch 140 is a dual-gate MISFET and the low-side switch 150 is a single-gate transistor, in other embodiments both switches may be implemented as dual-gate devices, each having independently controlled gate pairs. Such flexibility allows optimization of switching performance and power conversion efficiency depending on circuit topology, voltage class, and design requirements.

FIG. 2B illustrates a switching regulator 200A configured as a boost converter, according to an embodiment of the present disclosure. To avoid redundancy, components identical or similar to those described with reference to FIGS. 1A-2A are designated by the same reference numerals and their detailed descriptions are omitted.

In this embodiment, both the high-side switch 140 and the low-side switch 150 are implemented as dual-gate MISFETs. The high-side switch 140 includes the first drain 142, first source 144, first gate 146, and second gate 148, while the low-side switch 150 includes the second drain 152, second source 154, third gate 156, and fourth gate 158. The first source 144 of the high-side switch 140 and the second drain 152 of the low-side switch 150 are coupled to the common terminal 160, which serves as the switching node SW connected to the inductor L. The first drain 142 of the high-side switch 140 is connected to the output node 224 that provides the output voltage Vout, and the output capacitor Cout is coupled between the output node 224 and the ground potential 226 to smooth the output.

In operation, the inductor L stores energy when the low-side switch 150 is turned ON and releases energy to the output node 224 through the high-side switch 140 when the low-side switch 150 is turned OFF. Because both the high-side and low-side switches are dual-gate MISFETs, the conduction through each device can be controlled along multiple channel paths. The first gate 146 primarily controls current through a shorter conduction path (e.g., Path 1 in FIG. 1C), while the second gate 148 controls a longer conduction path (e.g., Path 2 in FIG. 1C) within the high-side device. Similarly, the third gate 156 and the fourth gate 158 control respective current paths in the low-side device, allowing independent modulation of its conduction characteristics.

The embodiment of FIG. 2B demonstrates the configuration in which both the high-side and low-side switches are dual-gate MISFETs within a boost-type regulator. Although not limited thereto, this arrangement allows symmetrical control of current flow and electric-field distribution across the switching devices.

FIG. 2C illustrates a block diagram of a switching regulator 270 configured as a boost converter, according to an embodiment of the present disclosure. To avoid redundancy, components identical or similar to those described with reference to FIGS. 1A-2B are denoted by the same reference numerals, and detailed descriptions thereof are omitted.

The switching regulator 270 includes a controller 280, high-side gate drivers 282, low-side gate drivers 284, and a bootstrap circuit 274. The controller 280 receives an input control signal (IN) and generates drive signals for operating the high-side switch 140 and the low-side switch 150 in a complementary manner. The high-side switch 140 is implemented as a dual-gate MISFET having first gate 146 and second gate 148, and the low-side switch 150 is likewise implemented as a dual-gate MISFET having third gate 156 and fourth gate 158.

The high-side gate drivers 282 are coupled between the controller 280 and the respective first and second gates 146 and 148. Each high-side gate driver 282 receives a bootstrap-derived drive voltage and applies an appropriate gate bias to its corresponding gate terminal. The low-side gate drivers 284 are supplied by a local driver supply voltage Vdd and are coupled to the third and fourth gates 156 and 158 of the low-side switch 150, respectively. The bootstrap circuit 274 includes bootstrap capacitor Cboot coupled between a supply node 278 of the high-side gate drivers 282 and the common terminal 160 (switching node SW). During operation, the bootstrap circuit 274 charges and discharges to generate a boosted voltage above the potential of the switching node SW, thereby enabling full enhancement of the high-side switch 140 during its ON interval.

The inductor L is connected between the input voltage Vin and the switching node SW, and the output node 276 delivers the output voltage Vout through the output capacitor Cout connected to ground potential 292. The high-side and low-side gate drivers 282, 284 are arranged such that the corresponding gate pairs (first and second gates 146, 148 for the high-side and third and fourth gates 156, 158 for the low-side) are driven either simultaneously or with controlled delay intervals, depending on the desired switching profile. The high-side and low-side switches 140 and 150 operate in a complementary manner to store energy in the inductor L during the low-side conduction phase and transfer energy to the output node 276 during the high-side conduction phase.

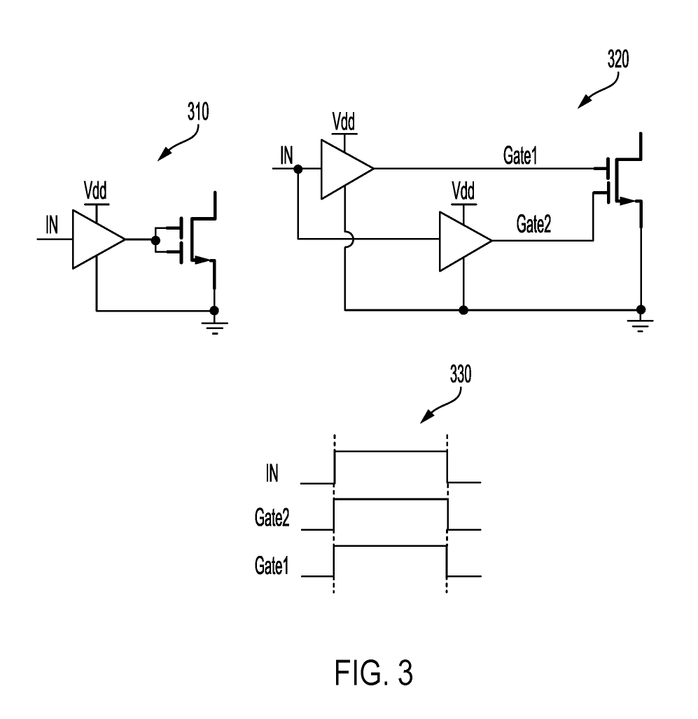

FIGS. 3 through 7 illustrate examples of gate-driver circuit configurations and switching-sequence schemes for operating the dual-gate MISFETs described in the foregoing embodiments. These configurations define alternative timing and control relationships between gate electrodes of each dual-gate device. Identical or similar circuit elements across the figures are denoted by the same reference numerals, and detailed repetition is omitted for clarity.

FIG. 3 illustrates representative dual-gate driver examples together with a corresponding timing diagram, according to an embodiment of the present disclosure. A standard single-gate driver 310 includes a simple inverter chain that can be used to drive both Gate 1 and Gate 2 simultaneously. A dual-gate driver 320 provides independent control of Gate 1 and Gate 2 using two buffer stages supplied by Vdd. The timing diagram 330 shows that Gate 1 and Gate 2 are simultaneously activated.

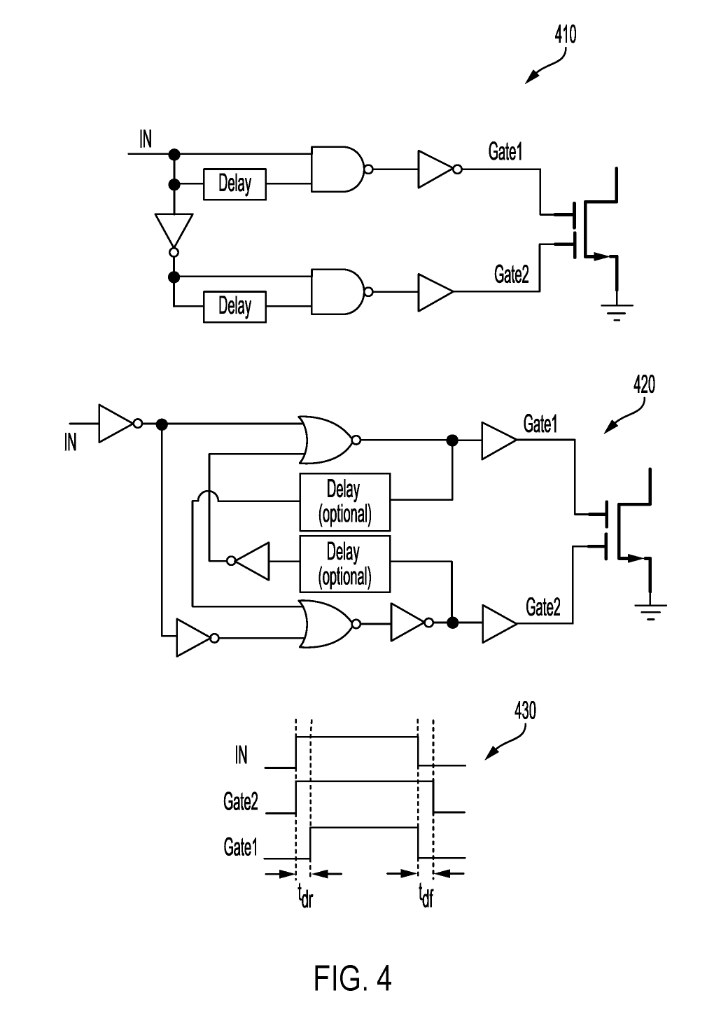

FIG. 4 illustrates logic-controlled driver configurations 410 and 420 that use logic gates and optional delay elements to generate the gate-drive signals, according to an embodiment of the present disclosure. In configuration 410, separate delay circuits and logic gates shape the input signal (IN) to produce sequential turn-on of Gate 2 followed by Gate 1. Configuration 420 employs another logic network in which optional delay elements set the propagation difference between the two outputs. The timing diagram 430 shows the corresponding delayed activation and deactivation of Gate 1 and Gate 2, with the rise-delay time (tdr) and fall-delay time (tdf) indicated between transitions. Here, tdr represents a delay applied during gate turn-on, while tdf represents a delay applied during gate turn-off.

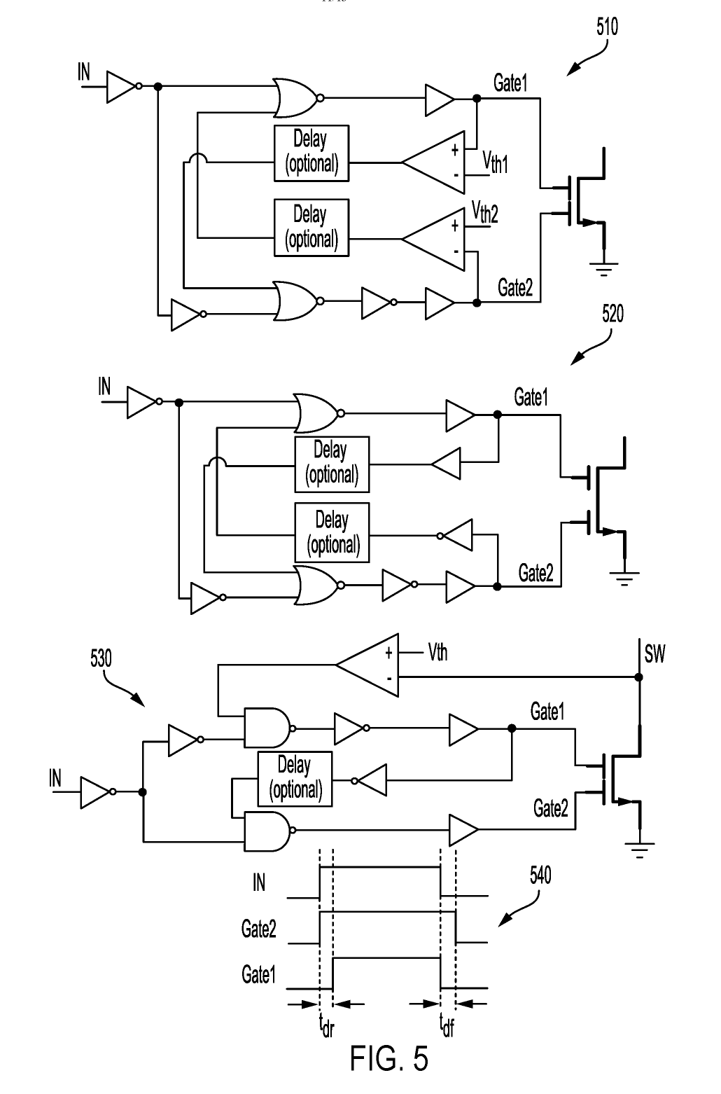

FIG. 5 illustrates alternative driver configurations 510-530 that incorporate optional delay elements and threshold-comparison stages, according to an embodiment of the present disclosure. In driver configuration 510, comparator blocks generate separate switching events for Gate 1 and Gate 2 when input thresholds Vth₁ and Vth₂ are reached. Driver configuration 530 illustrates a similar principle referenced to the switching node (SW) potential. Driver configuration 520 uses a logic inverter and buffer to generate separate switching events for Gate 1 and Gate 2 when the threshold of this logic is reached. The timing diagram 540 shows that each gate is driven with a controlled delay interval (tdr and tdf) relative to the input transition, enabling flexible sequencing during turn-on and turn-off.

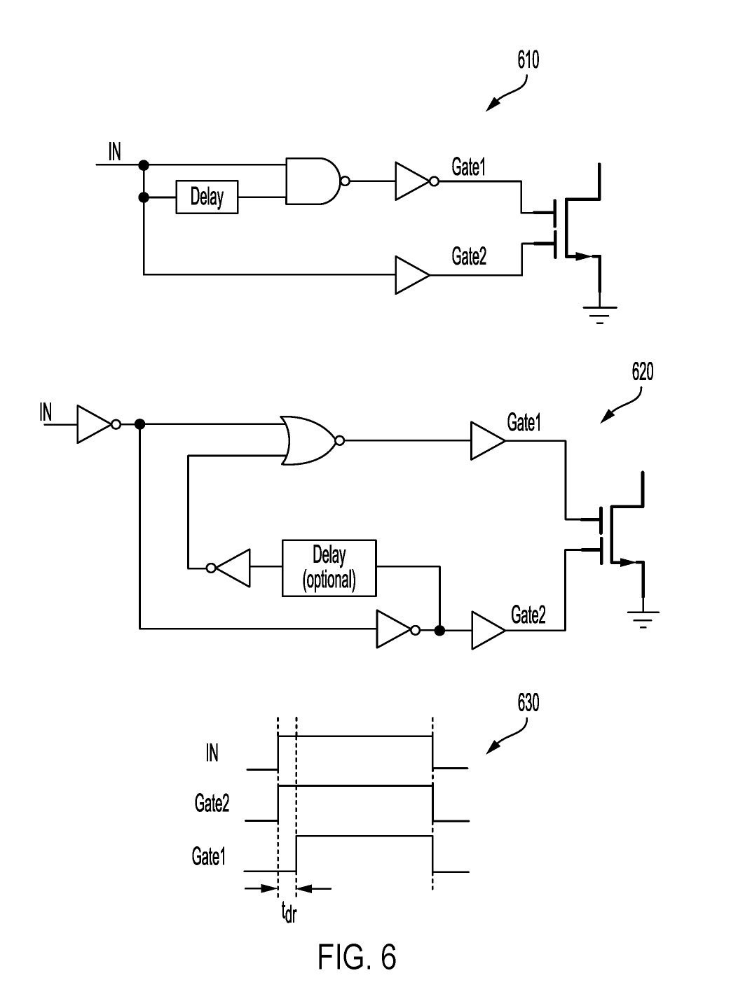

FIG. 6 illustrates dual-gate driver examples employing logic architectures, according to an embodiment of the present disclosure. In configuration 610, a delay element is inserted in one branch of a logic gate network so that Gate 1 receives a delayed drive signal while Gate 2 switches immediately with the input. Configuration 620 uses an optional delay block and an OR-type logic path to achieve a similar sequential control. The timing diagram 630 indicates that Gate 2 leads Gate 1 by a defined delay interval (tdr), providing controlled overlap or separation of the two gate signals during the low to high transition.

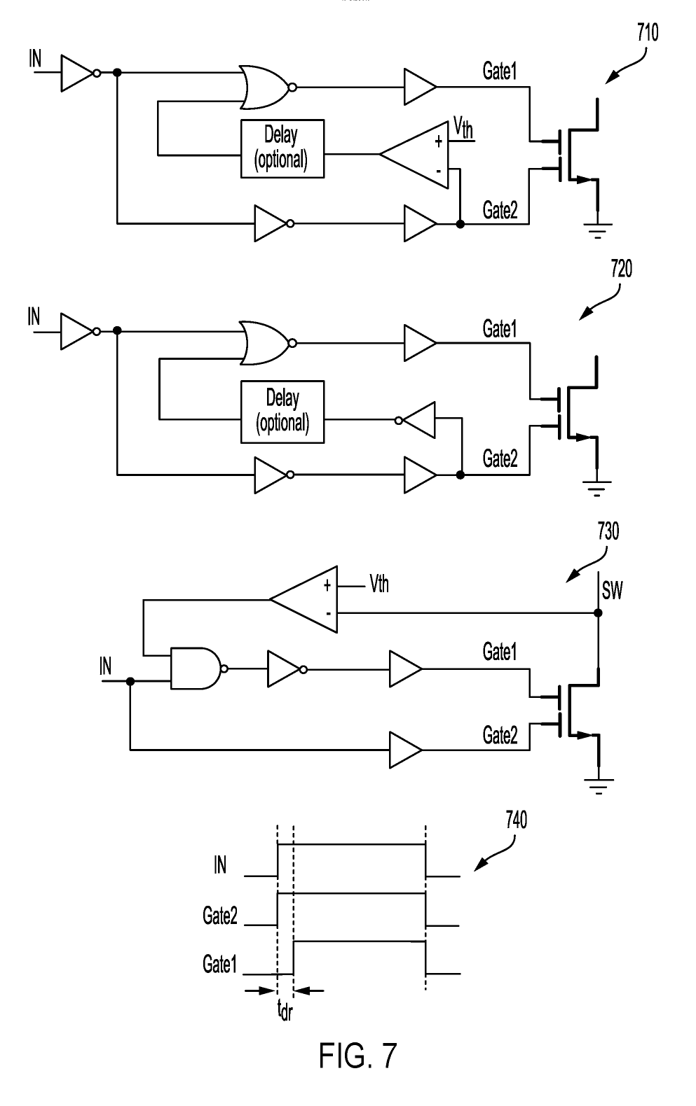

FIG. 7 illustrates additional driver configurations 710-730 that integrate comparator-based threshold detection with logic delay circuitry, according to an embodiment of the present disclosure. Driver configuration 710 generates delayed gate-drive signals as a function of an adjustable threshold voltage (Vth). Driver configuration 720 generates delayed gate-drive signals using an inverter as a threshold comparator while driver configuration 730 references Vth to the switching node (SW) potential for dynamic timing adaptation. The timing diagram 740 illustrates that Gate 2 again turns on first, followed by Gate 1 after a programmable delay (tdr), and Gate 1 and Gate 2 turn off simultaneously.

The driver and timing examples of FIGS. 3-7 collectively demonstrate alternative circuit topologies capable of realizing the gate-control relationships defined in the embodiments of FIGS. 1A-2C. The specific logic type, delay implementation, or threshold circuitry may vary depending on the intended application and switching-speed requirements. In the timing diagrams 330, 430, 540, 630, and 740, the relative delay times between the first gate and the second gate (e.g., tdr, tdf) may be selected within a range from about 0.01 ns to about 10 µs. The delay times tdr and tdf respectively represent (i) the time interval by which one gate is driven earlier than the other during a turn-on transition, and (ii) the time interval by which one gate is released earlier than the other during a turn-off transition. These delay values may also be set to zero, corresponding to embodiments in which the first and second gates are turned on and off simultaneously. The delay intervals may be arranged such that either the first gate or the second gate leads or lags during turn-on and/or turn-off, and any such timing scheme may be selectively implemented based on the driver logic illustrated in FIGS. 3-7.

### Examples

Example 1. A switching regulator comprising:
a high-side switch and a low-side switch coupled in series between an input voltage and a ground potential via a common terminal;
an inductor coupled to the common terminal; and
an output capacitor configured to generate an output voltage based on a current flowing through the inductor, wherein
the high-side switch is a first dual gate MISFET including a first gate, a second gate, a first source and a first drainthe
first dual gate MISFET has a first current path and a second current path, which are paths of a current flow from the first source to the first drain within the first dual gate MISFET,
the first gate controls a current flow through the first current path,
the second gate controls a current flow through the second current path, and
a length of the second current path is longer than a length of the first current path.

Example 2. The switching regulator according to Example 1, wherein
the first dual gate MISFET is an LDMOSFET (Laterally Diffused Metal-Oxide-Semiconductor Field Effect Transistor).

Example 3. The switching regulator according to any of Examples 1-2, wherein
in the first dual gate MISFET,
the first gate and the second gate are simultaneously turned on, and
the first gate and the second gate are simultaneously turned off.

Example 4. The switching regulator according to any of Examples 1-3, wherein
in the first dual gate MISFET,
at least one of:
the first gate is turned on after an elapse of a first delay time from when the second gate is turned on, and the second gate is turned off after an elapse of a second delay time from when the first gate is turned off, or
the second gate is turned on after an elapse of a first delay time from when the first gate is turned on, and the first gate is turned off after an elapse of a second delay time from when the second gate is turned off.

Example 5. The switching regulator according to Example 4, wherein
the first delay time is 0.01 ns or more and 10 μs or less, and
the second delay time is 0.01 ns or more and 10 μs or less.

Example 6. The switching regulator according to any of Examples 1-3, wherein
in the first dual gate MISFET,
at least one of:
the first gate is turned on after an elapse of a third delay time from when the second gate is turned on, and the first gate and the second gate are simultaneously turned off, or
the second gate is turned on after an elapse of a third delay time from when the first gate is turned on, and the first gate and the second gate are simultaneously turned off.

Example 7. The switching regulator according to Example 6, wherein
the third delay time is 0.01 ns or more and 10 μs or less.

Example 8. A switching regulator comprising:
a high-side switch and a low-side switch coupled in series between an input voltage and a ground potential via a common terminal;
an inductor coupled to the common terminal; and
an output capacitor configured to generate an output voltage based on a current flowing through the inductor, wherein
the high-side switch is a first dual gate MISFET including a first gate, a second gate, a first source and a first drain,
the first dual gate MISFET has a first current path and a second current path, which are paths of a current flow from the first source to the first drain within the first dual gate MISFET,
the first gate controls a current flow through the first current path,
the second gate controls a current flow through the second current path,
the low-side switch is a second dual gate MISFET including a third gate, a fourth gate, a second source and a second drain,
the second dual gate MISFET has a third current path and a fourth current path, which are paths of a current flow from the second source to the second drain within the second dual gate MISFET,
the third gate controls a current flow through the third current path,
the fourth gate controls a current flow through the fourth current path,
a length of the second current path is longer than a length of the first current path, and
a length of the fourth current path is longer than a length of the third current path.

Example 9. The switching regulator according to Example 8, further comprising:
gate drivers driving the first, second, third and fourth gates respectively;
a controller controlling the gate drivers; wherein
each gate is controlled independently by the controller via its corresponding driver, and
a group of the first and second gates and a group of the third and fourth gates are controlled in a complementary manner.

Example 10. The switching regulator according to Example 8 or 9, further comprising:
a bootstrap circuit including a bootstrap capacitor coupled between the gate driver of the first gate and the common terminal, wherein
the first dual gate MISFET is an N-channel MOSFET, and
the bootstrap circuit is configured to generate a boost voltage enhanced by a predetermined electric potential above a switching voltage at the common terminal.

Example 11. A switching regulator comprising:
an inductor and a high-side switch coupled in series between an input voltage and an output voltage via a common terminal;
a low-side switch coupled between the common terminal and a ground potential; and
an output capacitor configured to generate the output voltage based on a current flowing through the inductor, wherein
the high-side switch is a first dual gate MISFET including a first gate, a second gate, a
first source and a first drain,
the first dual gate MISFET has a first current path and a second current path from the first source to the first drain,
the first gate controls the first current path,
the second gate controls the second current path, and
a length of the second current path is longer than a length of the first current path.

Example 12. The switching regulator according to Example 11, wherein the first dual gate MISFET is an LDMOSFET.

Example 13. The switching regulator according to any of Examples 11-12, wherein the first and second gates are simultaneously turned on and simultaneously turned off.

Example 14. The switching regulator according to any of Examples 11-13, wherein
in the first dual gate MISFET,
at least one of:
the first gate is turned on after an elapse of a first delay time from when the second gate is turned on, and the second gate is turned off after an elapse of a second delay time from when the first gate is turned off, or
the second gate is turned on after an elapse of the first delay time from when the first gate is turned on, and the first gate is turned off after an elapse of the second delay time from when the second gate is turned off.

Example 15. The switching regulator according to Example 14, wherein
the first and second delay times are each between 0.01 ns and 10 μs.

Example 16. The switching regulator according to any of Examples 11-13, wherein
in the first dual gate MISFET,
at least one of:
the first gate is turned on after an elapse of a third delay time from when the second gate is turned on, and the first gate and the second gate are simultaneously turned off, or
the second gate is turned on after an elapse of a third delay time from when the first gate is turned on, and the first gate and the second gate are simultaneously turned off.

Example 17. The switching regulator according to Example 16, wherein
the third delay time is between 0.01 ns and 10 μs.

Example 18. A switching regulator comprising:
an inductor and a high-side switch coupled in series between an input voltage and an output voltage via a common terminal;
a low-side switch coupled between the common terminal and a ground potential; and
an output capacitor configured to generate the output voltage based on a current flowing through the inductor, wherein
the high-side switch is a first dual gate MISFET including a first gate, a second gate, a first source and a first drain;
the low-side switch is a second dual gate MISFET including a third gate, a fourth gate, a second source and a second drain;
each dual-gate MISFET includes corresponding short and long current paths; and
the long current paths of both devices are longer than their respective short current paths.

Example 19. The switching regulator according to Example 18, further comprising:
gate drivers driving each of the first, second, third and fourth gates; and
a controller configured to independently control each gate and to drive the first/second gate group and the third/fourth gate group in a complementary manner.

Example 20. The switching regulator according to Example 18 or 19, further comprising:
a bootstrap circuit including a bootstrap capacitor coupled between the gate drivers of
the first and second gates and the common terminal, wherein
the first dual gate MISFET is an N-channel MOSFET and
the bootstrap circuit generates a boosted voltage above the switching-node potential.

Example 21. A switching regulator comprising:
a high-side switch and a low-side switch coupled in series between an input voltage and a ground potential via a common terminal;
an inductor coupled to the common terminal; and
an output capacitor configured to generate an output voltage based on a current flowing through the inductor,
wherein
the high-side switch is a first dual-gate MISFET including a first gate electrode, a second gate electrode, a first source region, and a first drain region,
the first dual-gate MISFET has a first current path and a second current path, which are paths of a current flow from the first source region to the first drain region within the first dual-gate MISFET,
the first gate electrode controls a current flow through the first current path,
the second gate electrode controls a current flow through the second current path, and
a length of the second current path is longer than a length of the first current path.

Example 22. The switching regulator according to Example 21, wherein the first dual-gate MISFET further includes:
a drift layer of a first conductivity type formed on a semiconductor substrate;
a P-type body region of a second conductivity type opposite to the first conductivity type, the P-type body region being formed in the drift layer and located between the first gate electrode and the second gate electrode;
a drain region of the first conductivity type formed in the drift layer;
a source region of the first conductivity type formed on the P-type body region;
the first current path is a current path through the drift layer without detouring around the P-type body region; and
the second current path is a current path through the drift layer that detours around the P-type body region.

Example 23. The switching regulator according to any of Examples 21-22, wherein the drift layer is a laminated structure including a first drift layer and a second drift layer laminated in this order,
the P-type body region is located in the second drift layer and partially extends into the first drift layer,
the first current path is a current path from the source region to the drain region through the second drift layer without detouring around the P-type body region, and
the second current path is a current path from the source region to the drain region through both the first drift layer and the second drift layer while detouring around the P-type body region.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. “Optional” or “optionally” means that the subsequently described event or circumstance may or may not occur, and that the description includes instances where the event occurs and instances where it does not.

Spatially relative terms, such as “inner,” “outer,” “beneath,” “below,” “lower,” “above,” “upper,” “top,” “bottom,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” may encompass both an orientation of above and below. The device may be otherwise oriented (rotated 90 degrees or at other orientations) and the spatially relative descriptors used herein interpreted accordingly.

Approximating language, as used herein throughout the specification and claims, may be applied to modify any quantitative representation that could permissibly vary without resulting in a change in the basic function to which it is related. Accordingly, a value modified by a term or terms, such as “about”, “approximately” and “substantially”, are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise. “Approximately” as applied to a particular value of a range applies to both values, and unless otherwise dependent on the precision of the instrument measuring the value, may indicate +/−10% of the stated value(s).

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A switching regulator comprising:
a high-side switch and a low-side switch coupled in series between an input voltage and a ground potential via a common terminal;
an inductor coupled to the common terminal; and
an output capacitor configured to generate an output voltage based on a current flowing through the inductor, wherein
the high-side switch is a first dual gate MISFET including a first gate, a second gate, a first source and a first drain,
the first dual gate MISFET has a first current path and a second current path, which are paths of a current flow from the first source to the first drain within the first dual gate MISFET,
the first gate controls a current flow through the first current path,
the second gate controls a current flow through the second current path, and
a length of the second current path is longer than a length of the first current path.

2. The switching regulator according to claim 1, wherein
the first dual gate MISFET is an LDMOSFET (Laterally Diffused Metal-Oxide-Semiconductor Field Effect Transistor).

3. The switching regulator according to claim 1, wherein
in the first dual gate MISFET,
the first gate and the second gate are simultaneously turned on, and
the first gate and the second gate are simultaneously turned off.

4. The switching regulator according to claim 1, wherein
in the first dual gate MISFET, at least one of:
the first gate is turned on after an elapse of a first delay time from when the second gate is turned on, and the second gate is turned off after an elapse of a second delay time from when the first gate is turned off, or
the second gate is turned on after an elapse of a first delay time from when the first gate is turned on, and the first gate is turned off after an elapse of a second delay time from when the second gate is turned off.

5. The switching regulator according to claim 4, wherein
the first delay time is 0.01 ns or more and 10 µs or less, and
the second delay time is 0.01 ns or more and 10 µs or less.

6. The switching regulator according to claim 1, wherein
in the first dual gate MISFET,
at least one of:
the first gate is turned on after an elapse of a third delay time from when the second gate is turned on, and the first gate and the second gate are simultaneously turned off, or
the second gate is turned on after an elapse of a third delay time from when the first gate is turned on, and the first gate and the second gate are simultaneously turned off.

7. The switching regulator according to claim 6, wherein
the third delay time is 0.01 ns or more and 10 µs or less.

8. A switching regulator comprising:
a high-side switch and a low-side switch coupled in series between an input voltage and a ground potential via a common terminal;
an inductor coupled to the common terminal; and
an output capacitor configured to generate an output voltage based on a current flowing through the inductor, wherein
the high-side switch is a first dual gate MISFET including a first gate, a second gate, a first source and a first drain,
the first dual gate MISFET has a first current path and a second current path, which are paths of a current flow from the first source to the first drain within the first dual gate MISFET,
the first gate controls a current flow through the first current path,
the second gate controls a current flow through the second current path,
the low-side switch is a second dual gate MISFET including a third gate, a fourth gate, a second source and a second drain,
the second dual gate MISFET has a third current path and a fourth current path, which are paths of a current flow from the second source to the second drain within the second dual gate MISFET,
the third gate controls a current flow through the third current path,
the fourth gate controls a current flow through the fourth current path,
a length of the second current path is longer than a length of the first current path, and
a length of the fourth current path is longer than a length of the third current path.

9. The switching regulator according to claim 8, further comprising:
gate drivers driving the first, second, third and fourth gates respectively,
a controller controlling the gate drivers, wherein
each of the first, second, third and fourth gates are controlled independently by the controller via each gate driver, and
a group of the first and second gates and a group of the third and fourth gates are controlled in a complementary manner by the controller.

10. The switching regulator according to claim 8, further comprising:
a bootstrap circuit including a bootstrap capacitor coupled between a gate driver of the first gate and the common terminal, wherein
the first dual gate MISFET is N-channel MOSFET, and
the bootstrap circuit is configured to generate a boost voltage enhanced by a predetermined electric potential above a switching voltage at the common terminal.

11. A switching regulator comprising:
an inductor and a high-side switch coupled in series between an input voltage and an output voltage via a common terminal;
a low-side switch coupled between the common terminal and a ground potential; and
an output capacitor configured to generate the output voltage based on a current flowing through the inductor, wherein
the high-side switch is a first dual gate MISFET including a first gate, a second gate, a first source and a first drain,
the first dual gate MISFET has a first current path and a second current path, which are paths of a current flow from the first source to the first drain within the first dual gate MISFET,
the first gate controls a current flow through the first current path,
the second gate controls a current flow through the second current path, and
a length of the second current path is longer than a length of the first current path.

12. The switching regulator according to claim 11, wherein
the first dual gate MISFET is an LDMOSFET (Laterally Diffused Metal-Oxide-Semiconductor Field Effect Transistor).

13. The switching regulator according to claim 11, wherein
in the first dual gate MISFET,
the first gate and the second gate are simultaneously turned on, and
the first gate and the second gate are simultaneously turned off.

14. The switching regulator according to claim 11, wherein
in the first dual gate MISFET, at least one of:
the first gate is turned on after an elapse of a first delay time from when the second gate is turned on, and the second gate is turned off after an elapse of a second delay time from when the first gate is turned off, or
the second gate is turned on after an elapse of the first delay time from when the first gate is turned on, and the first gate is turned off after an elapse of the second delay time from when the second gate is turned off.

15. The switching regulator according to claim 14, wherein
the first delay time is 0.01 ns or more and 10 µs or less, and
the second delay time is 0.01 ns or more and 10 µs or less.

16. The switching regulator according to claim 11, wherein
in the first dual gate MISFET, at least one of:
the first gate is turned on after an elapse of a third delay time from when the second gate is turned on, and the first gate and the second gate are simultaneously turned off, or
the second gate is turned on after an elapse of a third delay time from when the first gate is turned on, and the first gate and the second gate are simultaneously turned off.

17. TThe switching regulator according to claim 16, wherein
the third delay time is 0.01 ns or more and 10 µs or less.

18. A switching regulator comprising:
an inductor and a high-side switch coupled in series between an input voltage and an output voltage via a common terminal;
a low-side switch coupled between the common terminal and a ground potential; and
an output capacitor configured to generate the output voltage based on a current flowing through the inductor, wherein
the high-side switch is a first dual gate MISFET including a first gate, a second gate, a first source and a first drain,
the first dual gate MISFET has a first current path and a second current path, which are paths of a current flow from the first source to the first drain within the first dual gate MISFET,
the first gate controls a current flow through the first current path,
the second gate controls a current flow through the second current path,
the low-side switch is a second dual gate MISFET including a third gate, a fourth gate, a second source and a second drain,
the second dual gate MISFET has a third current path and a fourth current path, which are paths of a current flow from the second source to the second drain within the second dual gate MISFET,
the third gate controls a current flow through the third current path,
the fourth gate controls a current flow through the fourth current path,
a length of the second current path is longer than a length of the first current path, and
a length of the fourth current path is longer than a length of the third current path.

19. The switching regulator according to claim 18, further comprising:
gate drivers driving the first gate, the second gate, the third gate and the fourth gate respectively; and
a controller controlling the gate drivers, wherein
each of the first, second, third and fourth gates are controlled independently by the controller via each gate driver, and
a group of the first and second gates and a group of the third and fourth gates are controlled in a complementary manner by the controller.

20. The switching regulator according to claim 18, further comprising:
a bootstrap circuit including a bootstrap capacitor coupled between gate drivers of the first and second gates and the common terminal, wherein
the first dual gate MISFET is N-channel MOSFET, and
the bootstrap circuit is configured to generate a boost voltage enhanced by a predetermined electric potential above a switching voltage at the common terminal.
